(19) United States
(12) Patent Application Publication
(10) Pub. No.: US 2014/0097407 A1
(43) Pub. Date: Apr. 10, 2014

(54) ORGANIC LIGHT EMITTING DISPLAY APPARATUS AND METHOD OF MANUFACTURING THE SAME

(71) Applicant: SAMSUNG DISPLAY CO., LTD., Yongin-city (KR)

(72) Inventor: Sang-Hun Oh, Yongin-city (KR)

(73) Assignee: SAMSUNG DISPLAY CO., LTD., Yongin-city (KR)

(21) Appl. No.: 13/791,383

(22) Filed: Mar. 8, 2013

(30) Foreign Application Priority Data
Oct. 10, 2012 (KR) 10-2012-0112656

(51) Int. Cl. H01L 51/52; H01L 51/56

(52) U.S. Cl. CPC H01L 51/5203; H01L 51/56
USPC 257/40; 257/88; 438/34

(57) ABSTRACT

An organic light emitting display apparatus and a method of manufacturing the same. The organic light emitting display apparatus includes a substrate; an insulating layer formed on the substrate and including a groove; a first electrode formed on the insulating layer so as to overlap at least with the groove; a pixel defining layer covering edges of the first electrode and including an opening that overlaps at least with the groove; an intermediate layer formed on the first electrode to overlap with the opening and including an organic emission layer; and a second electrode formed on the intermediate layer.

### CROSS-REFERENCE TO RELATED APPLICATIONS

This application claims the benefit of Korean Patent Application No. 10-2012-0112656, filed on Oct. 10, 2012, in the Korean Intellectual Property Office, the disclosure of which is incorporated herein in its entirety by reference.

### BACKGROUND

1. Field

The present embodiments relate to an organic light emitting display apparatus and a method of manufacturing the same, and more particularly, to an organic light emitting display apparatus capable of improving an image quality characteristic and a method of manufacturing the organic light emitting display apparatus.

2. Description of the Related Technology

Many display apparatuses have been replaced with thin flat panel display apparatuses that may be portable. Among such flat panel display apparatuses, organic light emitting display apparatuses are self-emissive display apparatuses having wide viewing angle, high contrast, and fast response speed, and thus, have been considered as next generation display apparatuses.

An organic light emitting display apparatus includes an intermediate layer, a first electrode, and a second electrode. The intermediate layer includes an organic emission layer. When a voltage is applied across the first and second electrodes, the organic emission layer emits visible light.

The intermediate layer efficiently emits light when being formed evenly on the first electrode, and, the intermediate layer has to be electrically connected with the first electrode without being spaced apart from the first electrode in a region corresponding to the first electrode in order to increase a light emission area and improve image quality characteristics of the organic light emitting display apparatus.

### SUMMARY

The present embodiments provide an organic light emitting display apparatus capable of improving image quality characteristics and a method of manufacturing the organic light emitting display apparatus.

According to an aspect of the present embodiments, there is provided an organic light emitting display apparatus including: a substrate; an insulating layer formed on the substrate and including a groove; a first electrode formed on the insulating layer so as to overlap at least with the groove; a pixel defining layer covering edges of the first electrode and including an opening that overlaps at least with the groove; an intermediate layer formed on the first electrode to overlap with the opening and comprising an organic emission layer; and a second electrode formed on the intermediate layer.

The first electrode may include a groove corresponding to the groove of the insulating layer.

The first electrode may be greater than the groove of the insulating layer.

The groove of the insulating layer may be formed to have a stepped shape.

The groove of the insulating layer may include at least one bent portion formed on a side surface of the groove.

An upper portion and a lower portion on the side surface of the groove based on the bent portion may have different inclinations from each other.

A lower portion on the side surface of the groove based on the bent portion may have an inclination that is less than an inclination of an upper portion of the side surface of the groove.

The first electrode may include a bent portion corresponding to the bent portion of the groove.

An upper portion and a lower portion of the first electrode based on the bent portion of the first electrode may have different inclinations from each other.

A lower portion of the first electrode based on the bent portion of the first electrode may have an inclination that is less than an inclination of an upper portion of the first electrode.

The pixel defining layer may include a bent portion to correspond to the bent portion of the groove.

An upper portion and a lower portion of the pixel defining layer based on the bent portion of the pixel defining layer may have different inclinations from each other.

A lower portion of the pixel defining layer based on the bent portion of the pixel defining layer may have an inclination that is less than an inclination of an upper portion of the pixel defining layer.

The organic light emitting display apparatus may further include a thin film transistor (TFT) formed on the substrate, electrically connected to the first electrode, and including an active layer, a gate electrode, a source electrode, and a drain electrode.

The insulating layer may be formed on the TFT.

According to another aspect of the present embodiments, there is provided a method of manufacturing an organic light emitting display apparatus, the method including: forming an insulating layer including a groove on a substrate; forming a first electrode on the insulating layer so as to overlap the groove; forming a pixel defining layer covering edges of the first electrode and comprising an opening overlapping at least the groove; forming an intermediate layer comprising an organic emission layer on the first electrode so as to overlap with the opening; and forming a second electrode on the intermediate layer.

The intermediate layer may be formed by a transferring method.

The groove of the insulating layer may be formed to have a stepped shape.

The groove of the insulating layer may include at least one bent portion on a side surface of the groove.

The groove of the insulating layer may be formed by using a half-tone mask.

### BRIEF DESCRIPTION OF THE DRAWINGS

The above and other features and advantages of the present embodiments will become more apparent by describing in detail example embodiments thereof with reference to the attached drawings in which:

FIG. 1 is a schematic cross-sectional view of an organic light emitting display apparatus according to an embodiment;

FIG. 2 is an enlarged view showing a portion A of FIG. 1;

FIG. 3 is a schematic cross-sectional view of an organic light emitting display apparatus according to another embodiment;

FIG. 4 is a schematic cross-sectional view of an organic light emitting display apparatus according to another embodiment; and

FIGS. 5A through 5F are cross-sectional views illustrating a method of manufacturing an organic light emitting display apparatus according to an embodiment.

### DETAILED DESCRIPTION

Hereinafter, structures and operations according to embodiments will be described with reference to accompanying drawings.

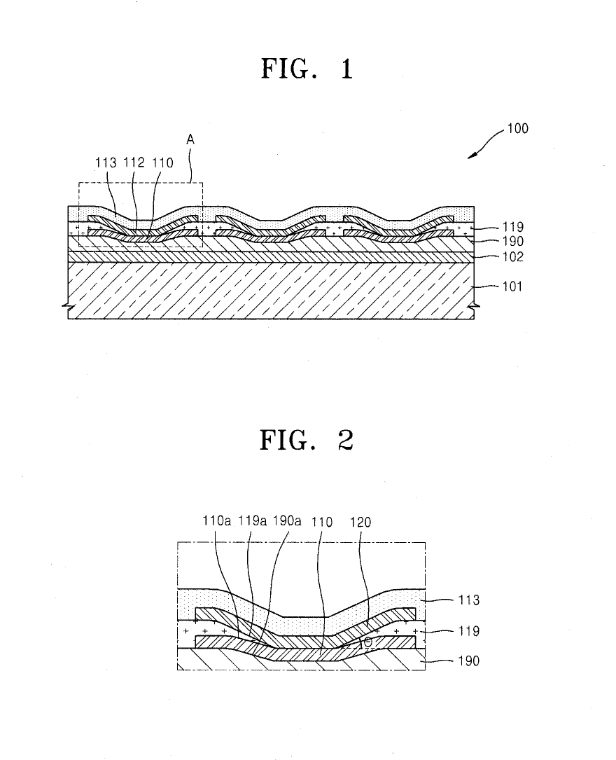

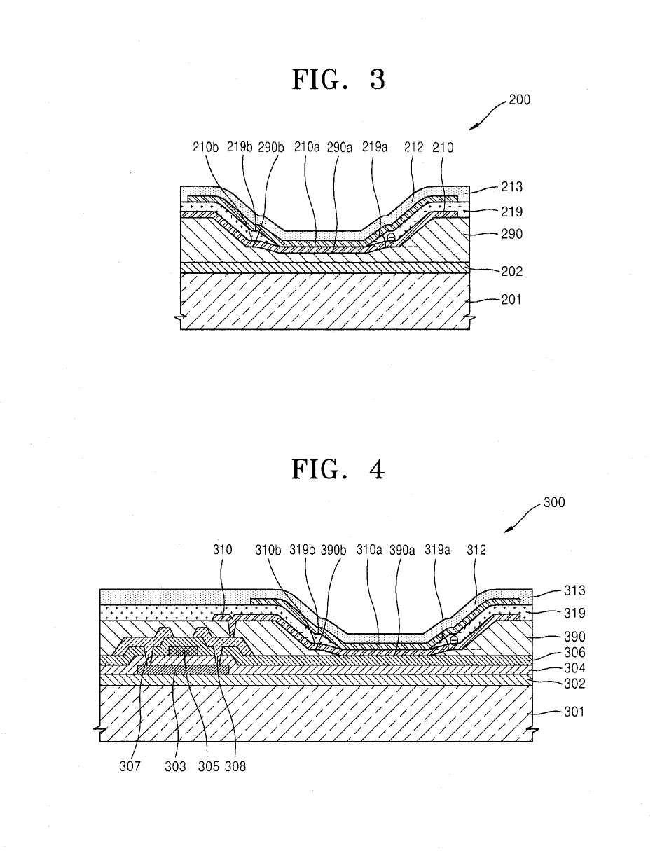

FIG. 1 is a schematic cross-sectional view of an organic light emitting display apparatus 100 according to an embodiment, and FIG. 2 is an enlarged view showing a portion A of FIG. 1.

Referring to FIGS. 1 and 2, the organic light emitting display apparatus 100 of the present embodiment includes a substrate 101, an insulating layer 190 including a groove 190a, a first electrode 110, a pixel defining layer 119, an intermediate layer 112, and a second electrode 113.

The substrate 101 may comprise a transparent glass material mainly including SiO₂. However, the present embodiments are not limited thereto, and the substrate 101 may comprise a transparent plastic material. Here, the plastic material forming the substrate 101 may be one or more selected from various organic materials.

A buffer layer 102 is formed on the substrate 101. The buffer layer 102 prevents impurity elements from infiltrating into the substrate 101 and provides a flat surface on the substrate 101. The buffer layer 102 may comprise various materials, for example, inorganic materials such as silicon oxide, silicon nitride, silicon aluminium oxide, aluminium nitride, titanium oxide, or titanium nitride, or organic materials such as polyimide, polyester, or acryl, in a form of a stacked substance including a plurality of materials stated above. Also, the buffer layer 102 may not an essential element, that is, may not be formed if necessary.

The insulating layer 190 is formed on the buffer layer 102. The insulating layer 190 includes the groove 190a. The groove 190a is formed to a predetermined depth. In FIGS. 1 and 2, the groove 190a is not connected to the buffer layer 102; however, the groove 190a may be formed to a deeper thickness to be connected to the buffer layer 102.

The first electrode 110 is formed on the insulating layer 190. The first electrode 110 is formed to overlap at least with the groove 190a of the insulating layer 190. For example, the first electrode 110 may be greater than the groove 190a. Since the first electrode 110 corresponds to the groove 190a of the insulating layer 190, the first electrode 110 includes a groove 110a that is similar to the groove 190a of the insulating layer 190.

The first electrode 110 functions as an anode and the second electrode 113 functions as a cathode, and vice versa.

If the first electrode 110 functions as an anode, the first electrode 110 may include indium tin oxide (ITO), indium zinc oxide (IZO), ZnO, or In₂O₃ having a high work function. In addition, the first electrode 110 may further include a reflective layer comprising Ag, Mg, Al, Pt, Pd, Au, Ni, Nd, Ir, Cr, Li, Yb, or Ca according to an objective and a design condition.

A pixel defining layer 119 is formed on the first electrode 110 by using an insulating material. Here, the pixel defining layer 119 includes an opening 119a that exposes at least a part of an upper surface of the first electrode 110. A side surface of the opening 119a forms a predetermined angle θ with the upper surface of the first electrode 110. Since the insulating layer 190 includes the groove 190a and the first electrode 110 also includes the groove 110a so as to correspond to the groove 190a, the side surface of the opening 119a of the pixel defining layer 119 has a slow inclination. The angle θ formed by the side surface of the opening 119a and the upper surface of the first electrode 110 may be controlled to be lower than 30°, for example, 20° or less.

An intermediate layer 112 is formed on the first electrode 110. Here, the intermediate layer 112 is formed to correspond to the opening 119a of the pixel defining layer 119 and to contact the pixel defining layer 119. An even and stable contact between the intermediate layer 112 and the first electrode 110 affects light emission characteristics of the intermediate layer 112. If the first electrode 110 and the intermediate layer 112 do not completely contact each other on a region where the first electrode 110 and the opening 119a of the pixel defining layer 119 contact each other, the light emission characteristics of the intermediate layer 112 may degrade. However, according to the present embodiment, the angle θ formed by the side surface of the opening 119a and the upper surface of the first electrode 110 is reduced by using the groove 190a of the insulating layer 190, and accordingly, the first electrode 110 and the intermediate layer 112 may contact each other to have a uniform characteristic. In particular, the intermediate layer 112 may stably contact the first electrode 110 and the pixel defining layer 119′ even in a region where the pixel defining layer 119, the first electrode 110, and the intermediate layer 112 contact each other.

The intermediate layer 112 includes an organic emission layer so as to display visible rays. The intermediate layer 112 may be formed as a low-molecular weight organic layer or a high-molecular weight organic layer. When the intermediate layer 112 is formed as a low-molecular weight organic layer, a single or multi-layer structure including a hole injection layer (HIL), a hole transport layer (HTL), an organic emission layer, an electron transport layer (ETL), and an electron injection layer (EIL) may be formed.

The HIL may comprise phthalocyanine compound such as copper phthalocyanine, or TCTA, m-MTDATA, or m-MTDAPB that is star-bust type amine.

The HTL may comprise N,N′-bis(3-methylphenyl)-N,N′-diphenyl-[1,1-biphenyl]-4,4′-diamine (TPD), N,N′-di(naphthalene-1-yl)-N,N′-diphenyl benzidine (α-NPD), and the like.

The EIL may comprise a material such as LiF, NaCl, CsF, Li₂O, BaO, or Liq.

The ETL may comprise Alg₃.

The organic emission layer may include a host material and a dopant material. The host material of the organic emission layer may be tris(8-hydroxyquinolinato)aluminium (Alq₃), 9,10-di(naphty-2-yl)anthracene (AND), 3-tert-butyl-9,10-bis-(β-naphthyl)-anthracene (TBADN), 4,4′-Bis(2,2-diphenylvinyl)-1,1′-biphenyl (DPVBi), 4,4′-Bis[2,2-di(4-methylphenyl)-1-yl]biphenyl (p-DMDPVBi), Tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), Bis(9,9-diarylfluorene)s (BDAF), 4,4′-bis(2,2-diphenyl-ethene-1-yl)-4,4′-di-(tert-butyl)phenyl (p-TDPVBi), N,N′-dicarbazolyl-3,5-benzene (mCP), 1,3,5-Tris(carbazol-9-yl)benzene (tCP), 4,4′,4″-Tris(carbazol-9-yl)triphenylamine (TcTa), 4,4′-N,N′-dicarbazole-biphenyl (CBP), 4,4′-bis(9-carbazolyl)-2,2′-dimethyl-biphenyl (CBDP), 4,4′-Bis(carbazol-9-yl)-9,9-dimethylfluorene (DMFL-CBP), 4,4′-bis(carbazole-9-yl)-9,9-bis(9-phenyl-9H-carbazole)fluorene (FL-4CBP), 4,4′-bis(carbazol-9-yl)-9,9-ditolylfluorene (DPFL-CBP), or 9,9-bis(9-phenyl-9H-carbazol)fluorene (FL-2CBP).

The dopant material of the organic emission layer may be 4,4′-bis[4-(di-p-tolylamino)styryl]biphenyl (DPAVBi), 9,10-di-(2-naphthyl)anthracene (ADN), or 2-tert-butyl-9,10-di(naphth-2-yl)anthracene (TBADN).

A second electrode 113 is formed on the intermediate layer 112. When the second electrode 113 functions as a cathode, the second electrode 113 may comprise metal such as Ag, Mg, Al, Pt, Pd, Au, Ni, Nd, Ir, Cr, Li, or Ca. Also, the second electrode 113 may include ITO, IZO, ZnO, or In₂O₃ so as to transmit light.

Although not shown in FIGS. 1 and 2, an encapsulation member (not shown) may be formed on the second electrode 113. The encapsulation member (not shown) may comprise various materials, for example, a substrate of a glass material, or an inorganic layer and an organic layer that are alternately stacked.

In the organic light emitting display apparatus 100 of the present embodiment, the insulating layer 190 is formed under the first electrode 110, and the insulating layer 190 includes the groove 190a. Since the first electrode 110 is formed to overlap with the groove 190a of the insulating layer 190, the first electrode 110 includes the groove 110a. The pixel defining layer 119 formed on the first electrode 110 includes the opening 119a, and the angle θ formed by the side surface of the opening 119a and the first electrode 110 is less than 30°, for example, 20° or less. The side surface of the opening 119a of the pixel defining layer 119 has a slow inclination. Thus, the intermediate layer 112 formed to correspond to the opening 119a is not lifted on the first electrode 110 and the pixel defining layer 119, but may effectively contact the first electrode 110 and the pixel defining layer 119. In particular, the first electrode 110 and the intermediate layer 112 evenly contact each other to be electrically connected to each other, and thus, the intermediate layer 112 may emit the light effectively.

Consequently, since the intermediate layer 112 emits the light effectively and the light emission area of the intermediate layer 112 increases, image quality characteristics of the organic light emitting display apparatus 100 may be improved.

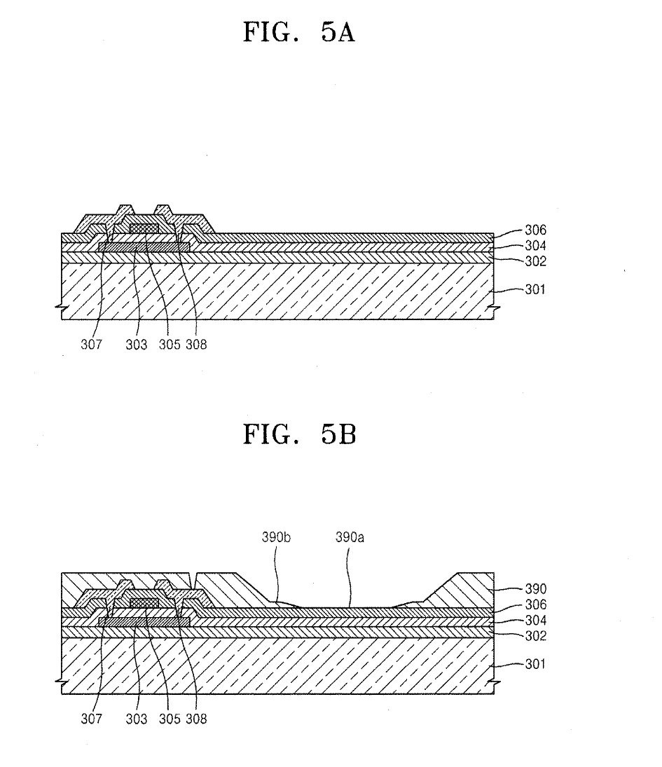

FIG. 3 is a schematic cross-sectional view of an organic light emitting display apparatus 200 according to another embodiment. Hereinafter, differences from the above embodiment will be described below for convenience of description.

Referring to FIG. 3, the organic light emitting display apparatus 200 according to the present embodiment includes a substrate 201, an insulating layer 290 including a groove 290a, a first electrode 210, a pixel defining layer 219, an intermediate layer 212, and a second electrode 213.

A buffer layer 202 is formed on the substrate 201. The buffer layer 202 prevents impurity elements from infiltrating into the substrate 201 and provides a flat surface on the substrate 201. The buffer layer 202 may comprise various materials performing the above functions. Also, the buffer layer 202 may not an essential element, that is, may not be formed if necessary.

The insulating layer 290 is formed on the buffer layer 202. The insulating layer 290 includes the groove 290a. The groove 290a is formed to a predetermined depth. In FIG. 3, the groove 290a is not connected to the buffer layer 202; however, the groove 290a may be formed to a deeper thickness to be connected to the buffer layer 202.

The groove 290a of the insulating layer 290 is formed in a stepped shape. At least one bent portion 290b is formed on a side surface of the groove 290a. In the present embodiment, since one bent portion 290b is formed on the side surface of the groove 290a, the groove 290a is formed to have a two-stepped side surface.

As such, an inclination of a lower portion of the side surface of the groove 290a may be effectively controlled to be slow. Based on the bent portion 290b of the groove 290a, the inclination of the lower portion thereof may be controlled to be slow and an inclination of an upper portion may be controlled higher. Thus, both a width and a depth of the groove 290a may be defined as desired.

The first electrode 210 is formed on the insulating layer 290. The first electrode 210 may be formed to overlap with at least the groove 290a of the insulating layer 290. For example, the first electrode 210 may be greater than the groove 290a. Since the first electrode 210 corresponds to the groove 290a of the insulating layer 290, the first electrode 210 includes a groove 210a that is similar to the groove 290a of the insulating layer 290.

The first electrode 210 includes a bent portion 210b. Based on the bent portion 210b of the first electrode 210, an inclination of a lower portion thereof may be controlled to be slow, and an inclination of an upper portion may be controlled higher.

The first electrode 210 may function as an anode and the second electrode 213 may function as a cathode, and vice versa.

The pixel defining layer 219 is formed on the first electrode 210 by using an insulating material. Here, the pixel defining layer 219 includes an opening 219a so as to expose at least a part of an upper surface of the first electrode 210. The opening 219a of the pixel defining layer 219 has a stepped shape. A bent portion 219b is formed on a side surface of the opening 219. As such, an inclination of a lower portion of the side surface of the pixel defining layer 219 may be effectively controlled to be slow. An angle θ formed by the side surface of the lower portion of the opening 219a of the pixel defining layer 219 and the upper surface of the first electrode 210 may be effectively reduced.

Also, since the opening 219a of the pixel defining layer 219 has the stepped shape, the angle θ is reduced while maintaining the depth of the opening 219a, for example, the thickness of the pixel defining layer 219, at a predetermined value or greater and maintaining the width of the opening 219a to be less than a predetermined value. Thus, a designing margin and processability of the organic light emitting display apparatus 200 may be improved.

The intermediate layer 212 is formed on the first electrode 210. Here, the intermediate layer 212 is formed to correspond to the opening 219a of the pixel defining layer 219 and contact the first electrode 210 and the pixel defining layer 219. An even and stable contact between the intermediate layer 212 and the first electrode 210 affects light emission characteristics of the intermediate layer 212. In particular, if the first electrode 210 and the intermediate layer 212 may not completely contact each other on a region where the first electrode 210 and the opening 219a of the pixel defining layer 219 contact each other, the light emission characteristics of the intermediate layer 212 may degrade. However, according to the present embodiment, the angle θ formed by the side surface of the opening 219a and the upper surface of the first electrode 210 is reduced by using the groove 290a of the insulating layer 290, and accordingly, the first electrode 210 and the intermediate layer 212 may contact each other to have a uniform characteristic. In particular, the intermediate layer 212 may stably contact the first electrode 210 and the pixel defining layer 219 in a region where the pixel defining layer 219, the first electrode 210, and the intermediate layer 212 contact each other.

The intermediate layer 212 includes an organic emission layer so as to display visible rays.

The second electrode 213 is formed on the intermediate layer 212.

Although not shown in FIG. 3, an encapsulation member (not shown) may be formed on the second electrode 213. The encapsulation member (not shown) may comprise various materials, for example, a substrate of a glass material, or an inorganic layer and an organic layer that are alternately stacked.

In the organic light emitting display apparatus 200 according to the present embodiment, the insulating layer 290 is formed under the first electrode 210, and the insulating layer 290 includes the groove 290a. The first electrode 210 overlaps the groove 290a of the insulating layer 290, and thus, the first electrode 210 also includes the groove 210a. The pixel defining layer 219 disposed on the first electrode 210 has the opening 219a, and the angle θ formed by the side surface of the opening 219a of the pixel defining layer 219 and the first electrode 210 is formed to be 30° or less. The side surface of the opening 219a of the pixel defining layer 219 has a slow inclination. As such, the intermediate layer 212 formed to correspond to the opening 219a is not lifted on the first electrode 210 and the pixel defining layer 219, but may effectively contact the first electrode 210 and the pixel defining layer 219. In particular, since the groove 290a of the insulating layer 290 has the bent portion 290b so that the side surface of the lower portion of the groove 290a has the slow inclination. Thus, the inclination of the lower portion of the opening 219a of the pixel defining layer 219 may be lowered effectively, and thus, the angle θ formed by the side surface of the opening 219a and the first electrode 210 may be easily reduced. In addition, the thickness of the pixel defining layer 219 is not excessively reduced and the width of the opening 219a is not excessively increased while reducing the angle θ, and thus, the pixel isolation function of the pixel defining layer 219 may be maintained and the design margin of the organic light emitting display apparatus 200 may be ensured.

Therefore, since the intermediate layer 212 may emit the light effectively and the light emission area of the intermediate layer 212 may be increased, the image quality characteristics of the organic light emitting display apparatus 200 may be improved.

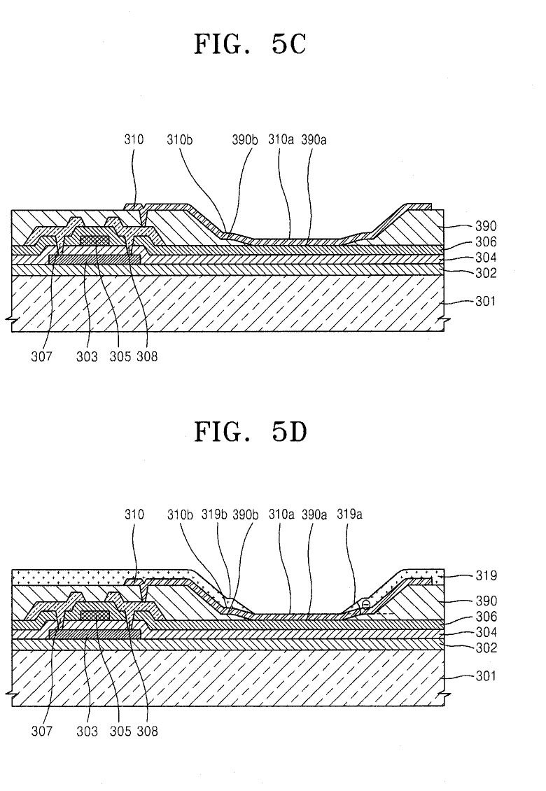

FIG. 4 is a schematic cross-sectional view of an organic light emitting display apparatus 300 according to another embodiment. The organic light emitting display apparatus 300 of the present embodiment includes a substrate 301, an insulating layer 390 including a thin film transistor (TFT) and a groove 390a, a first electrode 310, a pixel defining layer 319, an intermediate layer 312, and a second electrode 313.

The TFT includes an active layer 303, a gate electrode 305, a source electrode 307, and a drain electrode 308.

Differences from the previous embodiments will be described below for convenience of description.

A buffer layer 302 is formed on the substrate 301. The buffer layer 302 prevents impurity elements from infiltrating into the substrate 301 and provides a flat surface on the substrate 301. The buffer layer 302 may comprise various materials performing the above functions. Also, the buffer layer 302 may not an essential element, that is, may not be formed if necessary.

The active layer 303 of a predetermined pattern is formed on the buffer layer 302. The active layer 303 may comprise inorganic semiconductor such as amorphous silicon or polysilicon, or organic semiconductor or oxide semiconductor, and includes a source region, a drain region, and a channel region.

A gate insulating layer 304 is formed on the active layer 303, and the gate electrode 305 is formed on a predetermined region on the gate insulating layer 304. The gate insulating layer 304 is for insulating the active layer 303 and the gate electrode 305 from each other, and may comprise an organic material or an inorganic material such as SiNx and SiO₂.

The gate electrode 305 may include Au, Ag, Cu, Ni, Pt, Pd, Al, Mo, or an alloy such as Al:Nd alloy and Mo:W alloy; however, the present embodiments are not limited thereto. The gate electrode 305 may comprise various materials in consideration of attachability to adjacent layers, flatness, electric resistance, and processability.

An interlayer dielectric 306 is formed on the gate electrode 305. The interlayer dielectric 306 and the gate insulating layer 304 are formed to expose the source and drain regions of the active layer 303, and the source electrode 307 and the drain electrode 308 are formed to respectively contact the exposed source and drain regions of the active layer 303.

The source and drain electrodes 307 and 308 may comprise various conductive materials, and each may have a single-layered structure or a multi-layered structure.

The insulating layer 390 is formed on the source and drain electrodes 307 and 308. The insulating layer 390 is formed on the TFT to function as a passivation layer covering the TFT.

The insulating layer 390 includes the groove 390a. In FIG. 4, the groove 390a is formed to be connected to the interlayer dielectric 306; however, the groove 390a may be formed shallower to be separated from the interlayer dielectric 306.

The groove 390a of the insulating layer 390 is formed to have a stepped shape. One or more bent portions 390b are formed on a side surface of the groove 390a. In the present embodiment, since one bent portion 390b is formed on the side surface of the groove 390a, the groove 390a has the side surface of a two-stepped shape.

As such, an inclination of a lower portion on the side surface of the groove 390a may be controlled to be slow. Based on the bent portion 390b of the groove 390a, the inclination of the lower portion thereof may be controlled to be slow and an inclination of an upper portion may be controlled higher. Thus, both a width and a depth of the groove 390a may be defined as desired.

The groove 390a of the insulating layer 390 may be formed by using a photolithography method, in more detail, the groove 390a having the bent portion 390b and the stepped shape may be formed by using a half-tone mask.

The first electrode 310 is formed on the insulating layer 390. The insulating layer 390 is formed to expose a predetermined region of the drain electrode 308, not covering the entire drain electrode 308. The first electrode 310 is formed to be connected to the exposed drain electrode 308.

The first electrode 310 may be formed to overlap with at least the groove 390a of the insulating layer 390. For example, the first electrode 310 may be greater than the groove 390a. Since the first electrode 310 corresponds to the groove 390a of the insulating layer 390, the first electrode 310 includes a groove 310a that is similar to the groove 390a of the insulating layer 390.

The first electrode 310 includes a bent portion 310b. Based on the bent portion 310b of the first electrode 310, an inclination of a lower portion thereof may be controlled to be slow, and an inclination of an upper portion may be controlled higher.

The pixel defining layer 319 is formed on the first electrode 310 by using an insulating material. Here, the pixel defining layer 319 includes an opening 319a so as to expose at least a part of an upper surface of the first electrode 310. The opening 319a of the pixel defining layer 319 has a stepped shape. A bent portion 319b is formed on a side surface of the opening 319. As such, an inclination of a lower portion of the side surface of the pixel defining layer 319 may be effectively controlled to be slow. An angle θ formed by the side surface of the lower portion of the opening 319a of the pixel defining layer 319 and the upper surface of the first electrode 310 may be effectively reduced.

Also, since the opening 319a of the pixel defining layer 319 has the stepped shape, the angle θ is reduced while maintaining the depth of the opening 319a, for example, the thickness of the pixel defining layer 319, at a predetermined value or greater and maintaining the width of the opening 319a to be less than a predetermined value. Thus, a designing margin and processability of the organic light emitting display apparatus 300 may be improved.

The intermediate layer 312 is formed on the first electrode 310. Here, the intermediate layer 312 is formed to correspond to the opening 319a of the pixel defining layer 319 and contact the first electrode 310 and the pixel defining layer 319. An even and stable contact between the intermediate layer 312 and the first electrode 310 affects to light emission characteristics of the intermediate layer 312. If the first electrode 310 and the intermediate layer 312 may not completely contact each other on a region where the first electrode 310 and the opening 319a of the pixel defining layer 319 contact each other, the light emission characteristics of the intermediate layer 312 may degrade. However, according to the present embodiment, the angle θ formed by the side surface of the opening 319a and the upper surface of the first electrode 310 is reduced by using the groove 390a of the insulating layer 390, and accordingly, the first electrode 310 and the intermediate layer 312 may contact each other evenly. The intermediate layer 312 may stably contact the first electrode 310 and the pixel defining layer 319 in a region where the pixel defining layer 319, the first electrode 310, and the intermediate layer 312 contact each other.

The intermediate layer 312 includes an organic emission layer so as to display visible rays.

The second electrode 313 is formed on the intermediate layer 312.

Although not shown in FIG. 4, an encapsulation member (not shown) may be formed on the second electrode 313. The encapsulation member (not shown) may comprise various materials, for example, a substrate of a glass material, or an inorganic layer and an organic layer that are alternately stacked.

In the organic light emitting display apparatus 300 according to the present embodiment, the insulating layer 390 is formed under the first electrode 310, and the insulating layer 390 includes the groove 390a. The first electrode 310 overlaps the groove 390a of the insulating layer 390, and thus, the first electrode 310 also includes the groove 310a. The pixel defining layer 319 disposed on the first electrode 310 has the opening 319a, and the angle θ formed by the side surface of the opening 319a of the pixel defining layer 319 and the first electrode 310 is formed to be 30° or less, in more detail, 20° or less. The side surface of the opening 319a of the pixel defining layer 319 has a slow inclination. As such, the intermediate layer 312 formed to correspond to the opening 319a is not lifted on the first electrode 310 and the pixel defining layer 319, but may effectively contact the first electrode 310 and the pixel defining layer 319. Since the groove 390a of the insulating layer 390 has the bent portion 390b so that the side surface of the lower portion of the groove 390a has the slow inclination. Thus, the inclination of the lower portion of the opening 319a of the pixel defining layer 319 may be lowered effectively, and thus, the angle θ formed by the side surface of the opening 319a and the first electrode 310 may be easily reduced. In addition, the thickness of the pixel defining layer 319 is not excessively reduced and the width of the opening 319a is not excessively increased while reducing the angle θ, and thus, the pixel isolation function of the pixel defining layer 319 may be maintained and the design margin of the organic light emitting display apparatus 300 may be ensured.

Therefore, since the intermediate layer 312 may emit the light effectively and the light emission area of the intermediate layer 312 may be increased, the image quality characteristics of the organic light emitting display apparatus 300 may be improved.

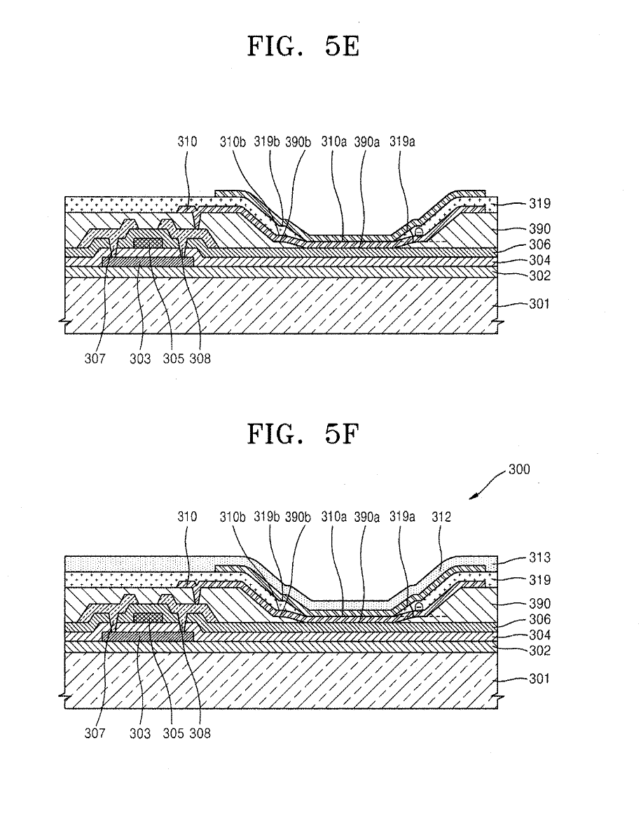

FIGS. 5A through 5F are cross-sectional views illustrating a method of manufacturing an organic light emitting display apparatus, for example, the organic light emitting display apparatus 300 shown in FIG. 4, according to an embodiment. Although not shown in FIGS. 5A through 5F, the method of the present embodiment may be applied to manufacture the organic light emitting display apparatuses 100 and 200 in the previous embodiments.

Referring to FIG. 5A, the buffer layer 302 is formed on the substrate 301, the active layer 303 is formed on the buffer layer 302, and the gate insulating layer 304 is formed on the active layer 303. In addition, the gate electrode 305 is formed on a predetermined region of the gate insulating layer 304, the interlayer dielectric 306 is formed on the gate electrode 305, and the source electrode 307 and the drain electrode 308 are formed on the interlayer dielectric 306. The buffer layer 302 prevents impurity elements from infiltrating into the substrate 301 and provides a flat surface on the substrate 301. The buffer layer 302 may comprise various materials performing the above functions. Also, the buffer layer 302 may not an essential element, that is, may not be formed if necessary.

Referring to FIG. 5B, the insulating layer 390 is formed on the source electrode 307 and the drain electrode 308. The insulating layer 390 includes the groove 390a. The groove 390 is formed to a predetermined depth. In FIG. 5B, the groove 390a is formed to be connected to the interlayer dielectric 306; however, the groove 390a may be formed shallower to be spaced apart from the interlayer dielectric 306.

The groove 390a of the insulating layer 390 is formed to have a stepped shape. One or more bent portions 390b are formed on a side surface of the groove 390a. In the present embodiment, since one bent portion 390b is formed on the side surface of the groove 390a, the groove 390a has the side surface of a two-stepped shape.

As such, an inclination of a lower portion on the side surface of the groove 390a may be controlled to be slow. Based on the bent portion 390b of the groove 390a, the inclination of the lower portion thereof may be controlled to be slow and an inclination of an upper portion may be controlled higher. Thus, both a width and a depth of the groove 390a may be defined as desired. In addition, referring to FIG. 5C, the first electrode 310 is formed on the insulating layer 390. The insulating layer 390 is formed to expose a predetermined region of the drain electrode 308, not covering the entire drain electrode 308. The first electrode 310 is formed to be connected to the exposed drain electrode 308.

The first electrode 310 may be formed to overlap with at least the groove 390a of the insulating layer 390. For example, the first electrode 310 may be greater than the groove 390a. Since the first electrode 310 corresponds to the groove 390a of the insulating layer 390, the first electrode 310 includes a groove 310a that is similar to the groove 390a of the insulating layer 390.

The first electrode 310 includes a bent portion 310b. Based on the bent portion 310b of the first electrode 310, an inclination of a lower portion thereof may be controlled to be slow, and an inclination of an upper portion may be controlled higher.

Referring to FIG. 5D, the pixel defining layer 319 is formed on the first electrode 310 by using an insulating material. Here, the pixel defining layer 319 includes the opening 319a so as to expose at least a part of an upper surface of the first electrode 310. The opening 319a of the pixel defining layer 319 has a stepped shape. A bent portion 319b is formed on a side surface of the opening 319. As such, an inclination of a lower portion of the side surface of the pixel defining layer 319 may be effectively controlled to be slow. An angle θ formed by the side surface of the lower portion of the opening 319a of the pixel defining layer 319 and the upper surface of the first electrode 310 may be effectively reduced.

Also, since the opening 319a of the pixel defining layer 319 has the stepped shape, the angle θ is reduced while maintaining the depth of the opening 319a, for example, the thickness of the pixel defining layer 319, at a predetermined value or greater and maintaining the width of the opening 319a to be less than a predetermined value. Thus, a designing margin and processability of the organic light emitting display apparatus 300 may be improved.

Then, referring to FIG. 5E, the intermediate layer 312 is formed on the first electrode 310 by using a transferring method such as a laser induced thermal imaging (LITI) method. In this case, the intermediate layer 312 stably contacts the pixel defining layer 319 and the first electrode 310 without lifting above the pixel defining layer 319 and the first electrode 310 according to the angle θ formed by the side surface of the lower portion of the opening 319a and the upper surface of the first electrode 310. In the present embodiment, the angle θ formed by the side surface of the lower portion of the opening 319a and the upper surface of the first electrode 310 is reduced so that the intermediate layer 312 may stably contact the pixel defining layer 319 and the first electrode 310.

The first electrode 310 and the intermediate layer 312 may effectively contact each other on a region where the first electrode 310 and the opening 319a of the pixel defining layer 319 contact each other.

The intermediate layer 312 includes an organic emission layer so as to display visible rays.

Referring to FIG. 5F, the second electrode 313 is formed on the intermediate layer 312.

Although not shown in FIGS. 5A through 5F, an encapsulation member (not shown) may be formed on the second electrode 313. The encapsulation member (not shown) may comprise various materials, for example, a substrate of a glass material, or an inorganic layer and an organic layer that are alternately stacked.

According to the present embodiment, the insulating layer 390 is formed under the first electrode 310, and the insulating layer 390 includes the groove 390a. Thus, the angle θ formed by the side surface of the opening 319a and the first electrode 310 may be easily reduced, and accordingly, the intermediate layer 312 may easily contact the pixel defining layer 319 and the first electrode 310 without lifting thereon so that the intermediate layer 312 may emit light effectively and the light emission area of the intermediate layer 312 may increase. Therefore, image quality characteristics of the organic light emitting display apparatus 300 may be improved.

According to the organic light emitting display apparatus and the method of manufacturing the organic light emitting display apparatus of the present embodiments, a durability and an electric characteristic of the organic light emitting display apparatus may be improved.

While the present embodiments have been particularly shown and described with reference to example embodiments thereof, it will be understood by those of ordinary skill in the art that various changes in form and details may be made therein without departing from the spirit and scope of the present embodiments as defined by the following claims.

What is claimed is:

1. An organic light emitting display apparatus comprising:
a substrate;
an insulating layer formed on the substrate and comprising a groove;
a first electrode formed on the insulating layer so as to overlap at least with the groove;
a pixel defining layer covering edges of the first electrode and including an opening that overlaps at least with the groove;
an intermediate layer formed on the first electrode overlapping with the opening and comprising an organic emission layer; and
a second electrode formed on the intermediate layer.

2. The organic light emitting display apparatus of claim 1, wherein the first electrode comprises a groove overlapping the groove of the insulating layer.

3. The organic light emitting display apparatus of claim 1, wherein the first electrode is larger than the groove of the insulating layer.

4. The organic light emitting display apparatus of claim 1, wherein the groove of the insulating layer has a stepped shape.

5. The organic light emitting display apparatus of claim 1, wherein the groove of the insulating layer comprises at least one bent portion formed on a side surface of the groove.

6. The organic light emitting display apparatus of claim 5, wherein an upper portion and a lower portion on the side surface of the groove with respect to the bent portion have different inclinations from each other.

7. The organic light emitting display apparatus of claim 5, wherein a lower portion on the side surface of the groove with respect to the bent portion has an inclination that is less than an inclination of an upper portion of the side surface of the groove.

8. The organic light emitting display apparatus of claim 5, wherein the first electrode comprises a bent portion corresponding to the bent portion of the groove.

9. The organic light emitting display apparatus of claim 8, wherein an upper portion and a lower portion of the first electrode with respect to the bent portion of the first electrode have different inclinations from each other.

10. The organic light emitting display apparatus of claim 8, wherein a lower portion of the first electrode with respect to the bent portion of the first electrode has an inclination that is less than an inclination of an upper portion of the first electrode.

11. The organic light emitting display apparatus of claim 5, wherein the pixel defining layer comprises a bent portion to correspond to the bent portion of the groove.

12. The organic light emitting display apparatus of claim 11, wherein an upper portion and a lower portion of the pixel defining layer with respect to the bent portion of the pixel defining layer have different inclinations from each other.

13. The organic light emitting display apparatus of claim 11, wherein a lower portion of the pixel defining layer with respect to the bent portion of the pixel defining layer has an inclination that is less than an inclination of an upper portion of the pixel defining layer.

14. The organic light emitting display apparatus of claim 1, further comprising a thin film transistor (TFT) formed on the substrate, electrically connected to the first electrode, and comprising an active layer, a gate electrode, a source electrode, and a drain electrode.

15. The organic light emitting display apparatus of claim 14 wherein the insulating layer is formed on the TFT.

16. A method of manufacturing an organic light emitting display apparatus, the method comprising:
forming an insulating layer including a groove on a substrate;
forming a first electrode on the insulating layer so as to overlap the groove;
forming a pixel defining layer covering edges of the first electrode and comprising an opening overlapping at least the groove;
forming an intermediate layer comprising an organic emission layer on the first electrode so as to overlap with the opening; and
forming a second electrode on the intermediate layer.

17. The method of claim 16, wherein the intermediate layer is formed by a transferring method.

18. The method of claim 16, wherein the groove of the insulating layer is formed to have a stepped shape.

19. The method of claim 16, wherein the groove of the insulating layer comprises at least one bent portion on a side surface of the groove.

20. The method of claim 19, wherein the groove of the insulating layer is formed by using a half-tone mask.
